(19) United States
(12) Patent Application Publication
(10) Pub. No.: US 2026/0088069 A1
(43) Pub. Date: Mar. 26, 2026

(54) MEMORY DEVICE PERFORMING PRECHARGE OPERATION AND OPERATING METHOD THEREOF

(71) Applicant: SK hynix Inc., Gyeonggi-do (KR)

(72) Inventors: Sang Hyun KU, Gyeonggi-do (KR); Do Hong KIM, Gyeonggi-do (KR); Don Hyun CHOI, Gyeonggi-do (KR)

(21) Appl. No.: 19/060,804

(22) Filed: Feb. 24, 2025

(30) Foreign Application Priority Data
Sep. 25, 2024 (KR) 10-2024-0129785

(51) Int. Cl. G11C 8/08; G11C 8/06; G11C 8/10

(52) U.S. Cl. CPC G11C 8/08; G11C 8/06; G11C 8/10

(57) ABSTRACT

A memory device includes cell mats in which a plurality of sub-word lines are arranged; a control signal generation circuit configured to generate a landing control signal to perform a soft landing operation on the plurality of sub-word lines according to a precharge command; a voltage supply circuit configured to provide a first supply voltage or a second supply voltage as an operating voltage according to a mat selection signal for selecting one of the cell mats and the landing control signal, the second supply voltage being less than the first supply voltage; and a word line driving circuit configured to drive a sub-word line selected by a row address among the plurality of sub-word lines based on the operating voltage.

### CROSS-REFERENCE TO RELATED APPLICATION

The present application claims priority under 35 U.S.C. § 119(a) to Korean Patent Application No. 10-2024-0129785, filed on Sep. 25, 2024, which is incorporated herein by reference in its entirety.

### BACKGROUND

### 1. Field

Various embodiments of the present disclosure relate to a semiconductor design technology, and more particularly, to a memory device including a word line driving circuit.

### 2. Description of the Related Art

As the degree of integration of a memory device increases, a distance between two adjacent word lines among a plurality of word lines included in the memory device decreases. As the distance between the adjacent word lines decreases, a coupling effect between adjacent word lines increases.

Whenever data is input and output to a memory cell, word lines toggle between an active state and an inactive state. Thus, as described above, the coupling effect between adjacent word lines increases, and data of memory cells connected to the frequently activated word lines are damaged. This phenomenon is called a row hammer, and various methods for mitigating the effect of a row hammer are being studied.

### SUMMARY

Embodiments of the present disclosure are directed to a memory device capable of adjusting an operating voltage of a word line driving circuit after an intermediate level section during a soft landing operation, and an operating method thereof.

According to an embodiment of the present disclosure, a memory device includes cell mats in which a plurality of sub-word lines are arranged; a control signal generation circuit configured to generate a landing control signal to perform a soft landing operation on the plurality of sub-word lines according to a precharge command; a voltage supply circuit configured to provide a first supply voltage or a second supply voltage as an operating voltage according to a mat selection signal for selecting one of the cell mats and the landing control signal, the second supply voltage less than the first supply voltage; and a word line driving circuit configured to drive a sub-word line selected by a row address among the plurality of sub-word lines based on the operating voltage.

According to an embodiment of the present disclosure, a memory device includes cell mats in which a plurality of main word lines are allocated; a plurality of main word line drivers configured to drive the plurality of main word lines based on an operating voltage; and a voltage supply circuit configured to selectively provide a first supply voltage or a second supply voltage, as the operating voltage, to main word line drivers driving main word lines allocated to a cell mat selected by a mat selection signal, according to a landing control signal for performing a soft landing operation for a precharge operation on the plurality of main word lines, the second supply voltage being less than the first supply voltage.

According to an embodiment of the present disclosure, an operating method of a memory device including cell mats in which a plurality of main word lines are allocated, wherein a plurality of sub-word lines are grouped to form one main word line of the plurality of main word lines, includes receiving a precharge command; providing a first supply voltage to main word lines allocated to a cell mat including a sub-word line selected from the plurality of sub-word lines while first discharging the selected sub-word line from a first voltage level to a second voltage level; and providing a second supply voltage to main word lines allocated to all cell mats while second discharging the selected sub-word line from the second voltage level to a third voltage level, the second supply voltage being less than the first supply voltage.

According to embodiments of the present disclosure, the memory device may supply an operating voltage of a main word line driver to a voltage lower than a high voltage by a certain level only in a preset section during the soft landing operation, thereby reducing the leakage current of unselected sub-word line drivers while preventing deterioration of discharge characteristics of a selected sub-word line.

### BRIEF DESCRIPTION OF THE DRAWINGS

FIGS. 1A and 1B are waveform diagrams for describing a soft landing scheme.

FIG. 2 is a block diagram illustrating a memory device in accordance with an embodiment of the present disclosure.

FIG. 3 is a diagram for describing a memory cell region of FIG. 2.

FIG. 4 is a detailed block diagram illustrating a row control circuit of FIG. 2.

FIG. 5 is a detailed circuit diagram illustrating a voltage supply circuit of FIG. 4.

FIGS. 6A and 6B are detailed circuit diagrams illustrating a main word line driving circuit of FIG. 4.

FIGS. 7A and 7B are detailed circuit diagrams illustrating a sub-word line driving circuit of FIG. 4.

FIG. 8 is a waveform diagram for describing an operation of a memory device according to an embodiment of the present disclosure.

FIG. 9 is a waveform diagram for describing an effect according to an embodiment of the present disclosure.

FIG. 10 is a block diagram illustrating a memory system according to an embodiment of the present disclosure.

### DETAILED DESCRIPTION

Various embodiments of the present disclosure will be described below in more detail with reference to the accompanying drawings. The present disclosure may have embodiments in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “connected” to another element, it may mean that the two are directly coupled or the two are electrically connected to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

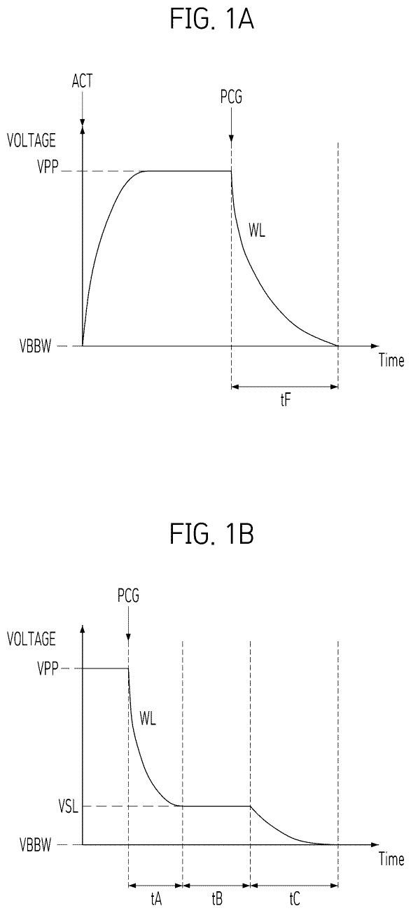

FIGS. 1A and 1B are waveform diagrams for describing a soft landing scheme according to an embodiment of the present disclosure.

Referring to FIG. 1A, when an active command ACT is applied for an access operation such as a read operation and a write operation of a memory device, a high voltage VPP is applied to a selected word line WL. When a precharge command PCG is applied, the selected word line WL is driven at a low voltage VBBW having a voltage level lower than the high voltage VPP. Therefore, a voltage level of the word line WL may exponentially decrease from a high voltage (VPP) level to a low voltage (VBBW) level according to an exponential curve.

At this time, a falling time tF in which the voltage level of the word line WL decreases from the high voltage (VPP) level to the low voltage (VBBW) level may affect the row hammer characteristics. The row hammer characteristics of adjacent word lines may deteriorate as the voltage level changes rapidly from the high voltage (VPP) level to the low voltage (VBBW) level. That is, as the falling time tF is shortened, the row hammer characteristic deterioration occurs.

Referring to FIG. 1B, a soft landing scheme (or operation) is proposed as a way to reduce the impact on the row hammer during a precharge operation. The soft landing scheme may reduce the row hammer effect by slowing the precharge of the word line WL or by maintaining or keeping the word line WL at an intermediate voltage (VSL) level for a certain amount of time before being discharged to the low voltage (VBBW) level from the high voltage (VPP) level, during the precharge operation.

That is, for the soft-landing scheme described in FIG. 1B, the precharge operation may be performed such that a voltage level of the word line WL decreases from the high voltage (VPP) level to the intermediate voltage (VSL) level during a first section tA, stays at the intermediate voltage (VSL) level during a second section tB and decreases from the intermediate voltage (VSL) level to the low voltage (VBBW) level during a third section tC. In this operation, a greater amount of the second section tB may improve the row hammer characteristics. However, it is difficult to secure the amount of the third section tC when the subsequent active command ACT is applied, which causes a failure (hereinafter referred to as “tRP logic failure”) due to a lack of margin for an internal operation that is performed according to a precharge-active time tRP. Therefore, the second section tB may be omitted or maintained for a short time.

Hereinafter, described will be a method of preventing the tRP logic failure and mitigating the row hammer during the precharge operation by lowering an operating voltage of a word line driving circuit by a certain level after the second section tB of the soft landing operation, according to an embodiment of the present disclosure.

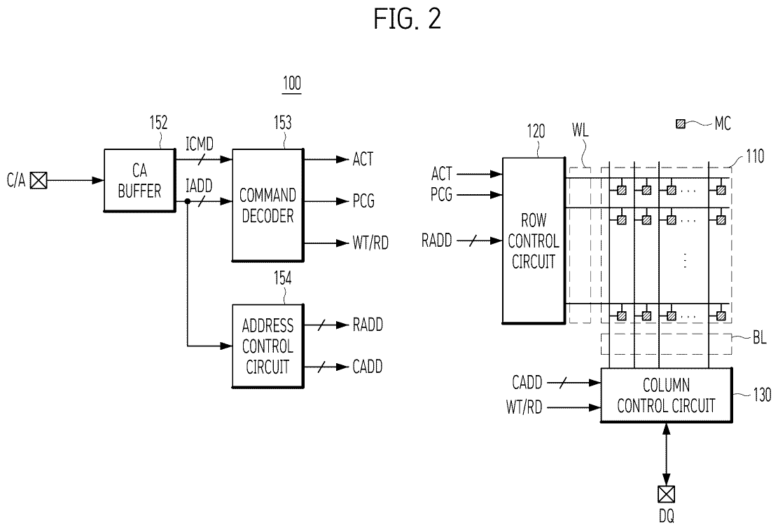

FIG. 2 is a block diagram illustrating a memory device 100 in accordance with an embodiment of the present disclosure.

Referring to FIG. 2, the memory device 100 may include a memory cell region 110, a row control circuit 120, a column control circuit 130, a command/address (CA) buffer 152, a command decoder 153, and an address control circuit 154.

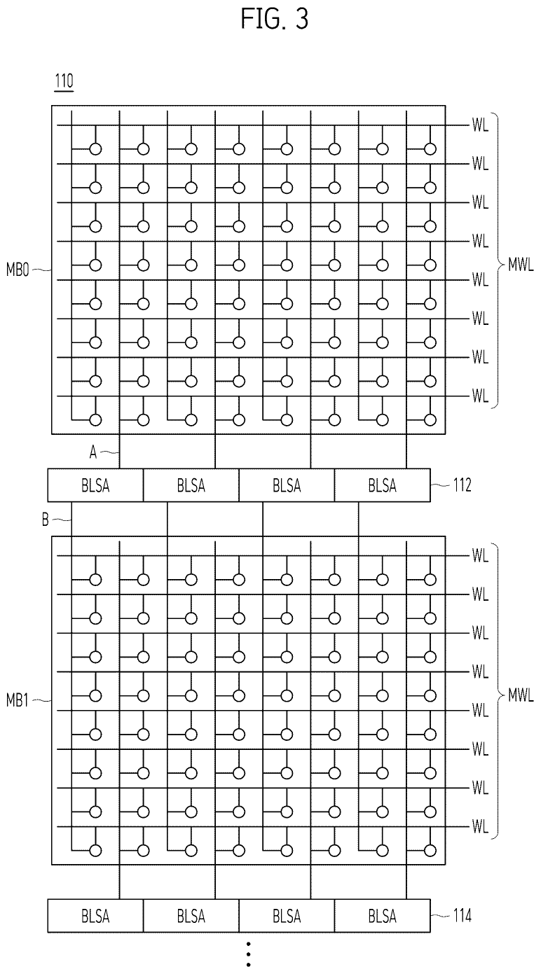

The memory cell region 110 may include a plurality of memory cells MC coupled to a plurality of word lines WL and a plurality of bit lines BL, the plurality of memory cells being arranged in the form of an array. The plurality of word lines WL may extend in a first direction (e.g., a row direction) and may be sequentially disposed in a second direction (e.g., a column direction) perpendicular to the first direction. The plurality of bit lines BL may extend in the column direction and may be sequentially disposed in the row direction. The plurality of memory cells MC may be composed of memory cells that require a refresh operation to secure data retention time. The memory cell region 110 may be composed of at least one bank. The number of banks or the number of memory cells MC may be determined depending on the capacity of the memory device 100. A detailed configuration of the memory cell region 110 will be described with reference to FIG. 3.

In the memory cell region 110, a plurality of cell mats (or a plurality of cell blocks) may be arranged. The plurality of cell mats is arranged in an array form in the row direction and the column direction. Each cell mat may include a plurality of memory cells MC coupled between a plurality of word lines WL and a plurality of bit lines BL. In an embodiment of the present disclosure, a “cell mat” may be defined as a set of memory cells which share the word lines WL and the bit lines BL and are arranged in the same form.

The CA buffer 152 may receive a command/address signal C/A from an external device (e.g., a memory controller). The CA buffer 152 may sample the command/address signal C/A and output an internal command ICMD and an internal address IADD.

The command decoder 153 may decode the internal command ICMD which is received from the CA buffer 152 to generate an active command ACT, a precharge command PCG, a read command RD and a write command WT. Although not illustrated, the command decoder 153 may additionally generate a refresh command, a mode register command, and the like by decoding the internal command ICMD.

The address control circuit 154 may classify the internal address IADD received from the CA buffer 152 as a row address RADD or a column address CADD. Depending on an embodiment, the address control circuit 154 may classify some bits of the internal address IADD as a row address RADD and classify the remaining bits as a column address CADD. The address control circuit 154 may classify the internal address IADD as a row address RADD when an active operation is directed as a result of the decoding by the command decoder 153 and may classify the internal address IADD as a column address CADD when a read or write operation is directed.

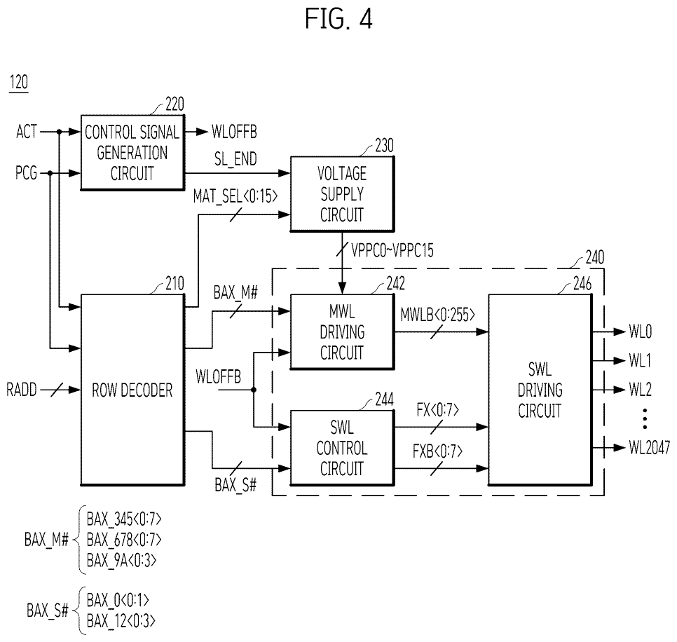

The row control circuit 120 may be coupled to the memory cell region 110 through the plurality of word lines WL. The row control circuit 120 may perform an active operation of activating a word line WL selected by the row address RADD according to the active command ACT and may perform a precharge operation of precharging the activated word line WL according to the precharge command PCG. In particular, as described in FIG. 1B, during the precharge operation, the row control circuit 120 may drive the activated word line WL such that a voltage level of the word line WL decreases from a high voltage (VPP) level to an intermediate voltage (VSL) level during a first section tA, stays at the intermediate voltage level VA during a second section tB and decreases from the intermediate voltage (VSL) level to a low voltage (VBBW) level during a third section tC. A detailed configuration of the row control circuit 120 will be described with reference to FIGS. 4 to 7B.

The column control circuit 130 may be coupled to the memory cell region 110 through the plurality of bit lines BL. The column control circuit 130 may select a predetermined number of the bit lines BL corresponding to the column address CADD, and input and output data DQ between the selected bit lines BL and a data pad, according to the read command RD or the write command WT. For example, the column control circuit 130 may include a column selection circuit and a data input/output circuit. The column selection circuit may decode the column address CADD to select a predetermined number of the bit lines BL. The data input/output circuit may receive the data DQ to be written to the memory cell region 110 during a write operation according to the write command WT and may transmit the data DQ read from the memory cell region 110 during a read operation according to the read command RD.

FIG. 3 is a diagram for describing the memory cell region 110 of FIG. 2.

Referring to FIG. 3, in the memory cell region 110, a plurality of cell mats MB0 and MB1 are disposed in a column direction. A predetermined number of word lines WL may be sequentially disposed in the cell mats MB0 and MB1 disposed in the column direction.

In the memory cell region 110, a first cell mat MB0, a second cell mat MB1, and first and second sense amplification circuits 112 and 114 disposed therebetween may be disposed. Subsequently, a third cell mat having the same structure as the first cell mat MB0 may be disposed below the second cell mat MB1.

The first sense amplification circuit 112 disposed between the first cell mat MB0 and the second cell mat MB1 may include a plurality of bit line sense amplifiers BLSA. Each bit line sense amplifier BLSA is shared by a bit line disposed on the first cell mat MB0 and a bit line disposed on the second cell mat MB1 to sense and amplify data transmitted through corresponding bit lines. For example, when the word line WL of the first cell mat MB0 is selected (or activated), data is transmitted to a bit line “A” disposed on the first cell mat MB0 and connected to the first sense amplification circuit 112. That is, the bit line “A” becomes a driving bit line, and a bit line “B” disposed on the second cell mat MB and connected to the first sense amplification circuit 112 becomes a reference bit line. Thereafter, the first sense amplification circuit 112 performs an amplification operation by sensing data transmitted through the bit line “A” and a voltage level of the bit line “B”. This sense amplification operation is performed in the same manner even when the bit line “A” is used as the reference bit line.

In order to improve a propagation delay of a voltage to the word lines, which occurs as the number of memory cells connected to the word lines increases and the distance between the word lines decreases, one main word line may be divided into a plurality (e.g., eight) sub-word lines and each sub-word line may be driven using sub-word line drivers. In FIG. 3, word lines WL of each cell mat may correspond to sub-word lines, and eight sub-word lines WL may be grouped to constitute one main word line MWL. In the following embodiment, the word lines WL will be referred to as sub-word lines WL. FIG. 3 illustrates a case where one main word line MWL is allocated to each cell mat, but the embodiment is not limited thereto, and a plurality of main word lines may be allocated to each cell mat. The row control circuit 120 may include sub-word line driving circuits for driving the sub-word lines WL and main word line driving circuits for driving the main word lines.

In an embodiment, for illustration, the memory cell region 110 includes 16 cell mats, 16 main word lines are disposed in each cell mat, and 8 sub-word lines are allocated to each main word line. As a result, 128 sub-word lines may be disposed in each cell mat, and 256 main word lines and 2048 sub-word lines may be disposed in the memory cell region 110.

FIG. 4 is a detailed block diagram illustrating the row control circuit 120 of FIG. 2.

Referring to FIG. 4, the row control circuit 120 may include a row decoder 210, a control signal generation circuit 220, a voltage supply circuit 230, and a word line driving circuit 240.

The row decoder 210 may decode the row address RADD to generate first address information BAX_M #, second address information BAX_S #, and a mat selection signal MAT_SEL<0:15>, where # means multiple.

The row decoder 210 may generate the first address information BAX_M # by decoding some bits (e.g., upper bits) of the row address RADD. For example, when the row address RADD includes 15 bits, the first address information BAX_M # may include an 8-bit signal BAX345<0:7> generated by decoding 4-th, 5-th, 6-th bits RADD<3:5> of the row address RADD<0:14>, and an 8-bit signal BAX678<0:7> generated by decoding 7-th, 8-th, 9-th bits RADD<6:8> of the row address RADD<0:14>, and a 4-bit signal BAX9A<0:3> generated by decoding 10-th, 11-th bits RADD<9:10> of the row address RADD<0:14>. In this case, only one bit of the signal BAX345<0:7> may be set to a high bit according to a logic value of the 4-th, 5-th, 6-th bits RADD<3:5>, and only one bit of the signal BAX678<0:7> may be set to a high bit according to a logic value of the 7-th, 8-th, 9-th bits RADD<6:8>, and only one bit of the signal BAX9A<0:3> may be set to a high bit according to a logic value of the 10-th, 11-th bits RADD<9:10>. As a result, one of 256 main word lines may be specified according to the 8-bit signal BAX345<0:7>, the 8-bit signal BAX678<0:7> and the 4-bit signal BAX9A<0:3>, which are included in the first address information BAX_M #.

The row decoder 210 may generate the second address information BAX_S # by decoding some bits (e.g., lower bits) of the row address RADD. For example, the second address information BAX_S # may include a 2-bit signal BAX0<0:1> generated by decoding a first bit RADD<0> of the row address RADD<0:14> composed of 15 bits, and a 4-bit signal BAX12<0:3> generated by decoding 2nd, 3rd bits RADD<1:2> of the row address RADD<0:14>. In this case, only one bit of the signal BAX0<0:1> may be set to a high bit according to a logic value of the first bit RADD<0:1>, and only one bit of the signal BAX12<0:3> may be set to a high bit according to a logic value of the 2nd, 3rd bits RADD<1:2>. As a result, one of eight sub-word lines allocated to one main word line may be specified according to the 2-bit signal BAX0<0:1> and the 4-bit signal BAX12<0:3>, which are included in the second address information BAS_S #.

The row decoder 210 may generate the mat selection signal MAT_SEL<0:15> composed of bits corresponding to cell mats by decoding the remaining bits (e.g., most significant bits) of the row address RADD. For example, the row decoder 210 may decode a 12-nd, 13-rd, 14-th, 15-th bits RADD<11:14> of the row address RADD<0:14> composed of 15 bits to activate one bit of the mat selection signal MAT_SEL<0:15> composed of 16 bits. As a result, one cell mat may be specified according to the mat selection signal MAT_SEL<0:15>.

The row decoder 210 may latch the row address RADD according to the active command ACT and the precharge command PCG, and decode the latched row address to generate the first address information BAX_M #, the second address information BAX_S #, and the mat selection signal MAT_SEL<0:15>, to thereby control an activation timing of each signal. According to an embodiment, the row decoder 210 may generate a delayed precharge signal by delaying the precharge command PCG for a predetermined time, and latch the row address RADD according to the delayed precharge signal and the active command ACT.

The control signal generation circuit 220 may generate a landing control signal SL_END and a word line activation signal WLOFFB according to the active command ACT and the precharge command PCG. In particular, the control signal generation circuit 220 may perform a soft landing operation by adjusting an activation timing of the landing control signal SL_END and the word line activation signal WLOFFB according to the precharge command PCG. The control signal generation circuit 220 may adjust the activation timing of the landing control signal SL_END and the word line activation signal WLOFFB according to the precharge command PCG, to divide a soft landing operation into a first section tA, a second section tB, and a third section Tc. In the first section tA, a voltage level of the word line WL decreases from a high voltage (VPP) level to an intermediate voltage (VSL) level. In the second section tB, the intermediate voltage level VA is maintained. In the third section tC, the voltage level of the word line WL decreases from the intermediate voltage (VSL) level to a low voltage (VBBW) level. The timing of the landing control signal SL_END and the word line activation signal WLOFFB may be adjusted according to the soft landing operation scheme.

For example, the control signal generation circuit 220 may generate the word line activation signal WLOFFB that is activated to a logic high level according to the active command ACT, and deactivated to a logic low level according to the precharge command PCG while maintaining the logic high level again during the second section tB. Furthermore, the control signal generation circuit 220 may generate the landing control signal SL_END that is activated to a logic high level according to the active command ACT and deactivated to a logic low level after a predetermined time from an input of the precharge command PCG. The predetermined time may be a time for designating an end time point of the first section tA of the soft landing operation. The landing control signal SL_END may distinguish the second section tB and the third section tC, from the first section tA. That is, the landing control signal SL_END may maintain a logic high level during the active operation and during the first section tA of the precharge operation, and maintain a logic low level during the second section tB and the third section tC.

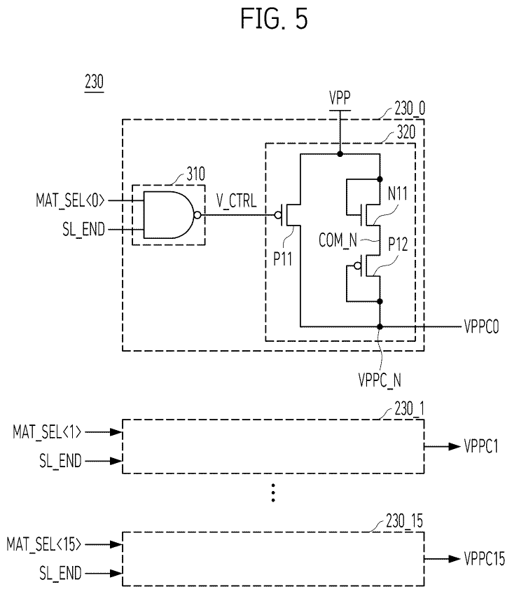

The voltage supply circuit 230 may provide a first supply voltage or a second supply voltage as an operating voltage VPPC0 to VPPC15 according to the mat selection signal MAT_SEL<0:15> and the landing control signal SL_END. The first supply voltage may have a high voltage (VPP) level, and the second supply voltage may have a (VPP-Δ) level that is decreased by a preset level A from the high voltage VPP. For example, the preset level A may be set to a multiple of a threshold voltage of a transistor (e.g., n*Vth, n is an integer greater than or equal to 1). The voltage supply circuit 230 may provide a first supply voltage VPP to main word lines disposed on a cell mat selected by the mat selection signal MAT_SEL<0:15> for the first section tA defined by the landing control signal SL_END, and provide a second supply voltage VPP-Δ to main word lines disposed on unselected cell mats, during the precharge operation. On the other hand, the voltage supply circuit 230 may provide the second supply voltage VPP-Δ to the main word lines disposed in all cell mats during the second section tB and the third section tC. A detailed configuration of the voltage supply circuit 230 will be described with reference to FIG. 5.

The word line driving circuit 240 may drive a sub-word line selected according to the row address RADD among the 2048 sub-word lines WL0 to WL2047 based on the operating voltage VPPC0 to VPPC15. The word line driving circuit 240 may include a main word line (MWL) driving circuit 242, a sub-word line (SWL) control circuit 244, and a sub-word line (SWL) driving circuit 246.

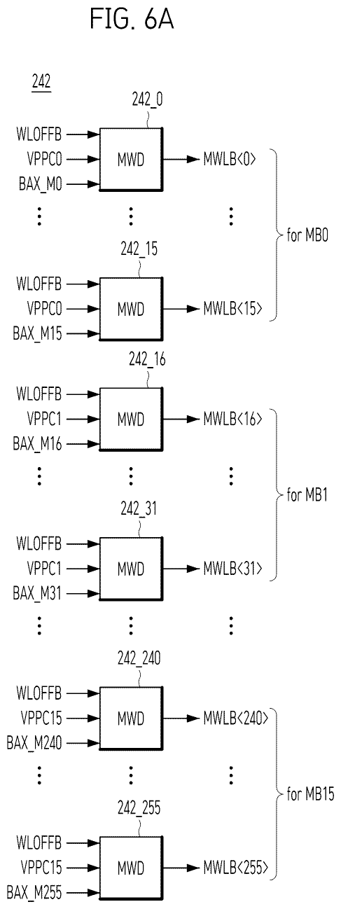

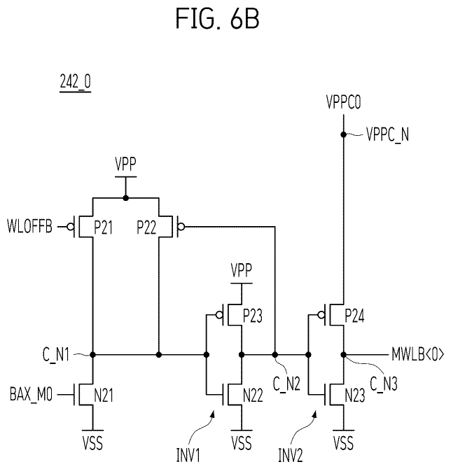

The main word line driving circuit 242 may generate a main driving signal MWLB<0:255> according to the first address information BAX_M # and the word line activation signal WLOFFB, based on the operating voltage VPPC0 to VPPC15. The main word line driving circuit 242 may include 256 main word line drivers (242_0 to 242_255 of FIG. 6A), respectively, for driving the 256 main word lines. Each bit of the main driving signal MWLB<0:255> may be allocated for driving the 256 main word lines, respectively, and used for specifying one of the 256 main word lines. The main word line driving circuit 242 may select one of the 256 main word line drivers 242_0 to 242_255 according to the first address information BAX_M #, and control an activation timing of a signal output from the selected main word line driver according to the word line activation signal WLOFFB. A detailed configuration of the main word line driving circuit 242 will be described in FIGS. 6A and 6B.

The sub-word line control circuit 244 may generate first and second sub-driving signals FX<0:7> and FXB<0:7> according to the second address information BAX_S # and the word line activation signal WLOFFB. The sub-word line control circuit 244 may generate the first and second sub-driving signals FX<0:7> and FXB<0:7> corresponding to the second address information BAX_S #, while controlling activation timings of the first and second sub-driving signals FX<0:7> and FXB<0:7> according to the word line activation signal WLOFFB. The first and second sub-driving signals FX<0:7> and FXB<0:7> may be used to specify one of eight sub-word lines allocated to one main word line.

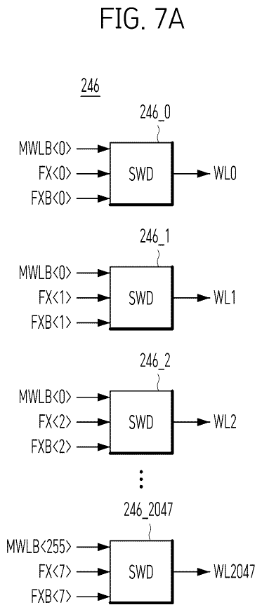

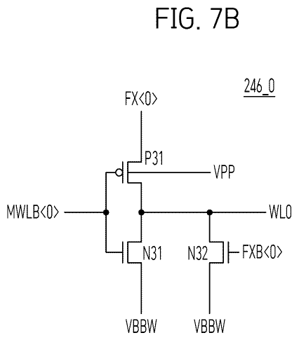

The sub-word line driving circuit 246 may drive the 2048 sub-word lines WL0 to WL2047 according to the main driving signal MWLB<0:255> and the first and second sub-driving signals FX<0:7> and FXB<0:7>. The sub-word line driving circuit 246 may include 2048 sub-word line drivers (246_0 to 246_2047 of FIG. 7A), respectively, for driving the 2048 sub-word lines WL0 to WL2047. A detailed configuration of the sub-word line driving circuit 246 will be described with reference to FIGS. 7A and 7B.

FIG. 5 is a detailed circuit diagram illustrating the voltage supply circuit 230 of FIG. 4.

Referring to FIG. 5, the voltage supply circuit 230 may include first to 16-th cell mat voltage supply circuits 230_0 to 230_15 corresponding to first to 16-th cell mats, respectively. Since the first to 16-th cell mat voltage supply circuits 230_0 to 230_15 have substantially the same configuration, the first cell mat voltage supply circuit 230_0 will be described in detail.

The first cell mat voltage supply circuit 230_0 may include a control part 310 and a supply part 320.

The control part 310 may generate a voltage control signal V_CTRL according to the mat selection signal MAT_SEL<0> and the landing control signal SL_END. For example, the control part 310 may be implemented with a NAND gate for performing a logic NAND operation on the mat selection signal MAT_SEL<0> and the landing control signal SL_END. With the above configuration, when a corresponding cell mat is selected according to the mat selection signal MAT_SEL<0>, the control part 310 may invert the landing control signal SL_END to output the voltage control signal V_CTRL. As a result, the voltage control signal V_CTRL may be activated to a logic low level during the active operation and during the first section tA of the precharge operation.

The supply part 320 may provide the first supply voltage VPP or the second supply voltage VPP-Δ as the operating voltage VPPC0 according to the voltage control signal V_CTRL. The supply part 320 may output the first supply voltage VPP when the voltage control signal V_CTRL is activated to a logic low level, and output the second supply voltage VPP-Δ when the voltage control signal V_CTRL is deactivated to a logic high level.

The supply part 320 may include first and second PMOS transistors P11 and P12 and an NMOS transistor N11.

The first PMOS transistor P11 may be coupled between a high voltage (VPP) node and a first node (VPPC_N), and receive the voltage control signal V_CTRL as a gate. The first PMOS transistor P11 may operate as a switch element that is turned on according to the voltage control signal V_CTRL. The first PMOS transistor P11 may transmit the high voltage VPP to the first node VPPC_N according to the voltage control signal V_CTRL.

The first NMOS transistor N11 may be between the high voltage (VPP) node and a common node COM_N, and have a gate and a drain, which are diode-coupled. The second PMOS transistor P12 may be between the common node COM_N and the first node VPPC_N, and have a gate and a drain, which are diode-coupled. That is, the first NMOS transistor N11 and the second PMOS transistor P12 may be diode-coupled in series between the high voltage (VPP) node and the first node VPPC_N, and clamp the high voltage VPP to transmit the clamped voltage to the first node VPPC_N. When the first PMOS transistor P11 is turned off, a voltage level of the first node VPPC_N may be adjusted by the first NMOS transistor N11 and the second PMOS transistor P12 so as not to fall below a voltage level calculated by subtracting a sum of a threshold voltage of the NMOS transistor and a threshold voltage of the PMOS transistor, from the high voltage VPP. The operating voltage VPPC0 may be output from the first node VPPC_N.

With the above configuration, each of the cell mat voltage supply circuits 230_0 to 230_15 may provide the first supply voltage VPP as an operating voltage during the first section tA in which the first PMOS transistor P11 is turned on when a corresponding mat selection signal is activated during the precharge operation. Further, each of the cell mat voltage supply circuits 230_0 to 230_15 may provide the second supply voltage VPP-Δ as an operating voltage during the second section tB and the third section tC in which the first PMOS transistor P11 is turned off during the precharge operation.

FIGS. 6A and 6B are detailed circuit diagrams illustrating the main word line driving circuit 242 of FIG. 4.

Referring to FIG. 6A, the main word line driving circuit 242 may include first to 256-th main word line drivers 242_0 to 242_255. The first to 256-th main word line drivers 242_0 to 242_255 may be selected (or enabled) according to the first address information BAX_M # to output the main driving signal MWLB<0:255> corresponding to the word line activation signal WLOFFB based on the operating voltage VPPC0 to VPPC15. The first to 256-th main word line drivers 242_0 to 242_255 may receive an operating voltage in units of cell mats. For example, the first to 16-th main word line drivers 242_0 to 242_15 may receive the operating voltage VPPC0 for the first cell mat MB0, and the 17-th to 31-st main word line drivers 242_16 to 242_31 may receive the operating voltage VPPC1 for the second cell mat MB1, and in this way, the 241-th to 256-th main word line drivers 242_240 to 242_255 may receive the operating voltage VPPC15 for the 16-th cell mat MB15.

Since the first to 256-th main word line drivers 242_0 to 242_255 have substantially the same configuration, the first main word line driver 242_0 will be described as an example. Referring to FIG. 6B, the first main word line driver 242_0 may include first to fourth PMOS transistors P21 to P24, and first to third NMOS transistors N21 to N23. The first PMOS transistor P21 and the second PMOS transistor P22 may be referred to as pull-up transistors, and the first NMOS transistor N21 may be referred to as a bias transistor.

The first PMOS transistor P21 may be coupled between a high voltage (VPP) node and a second node C_N1, and receive the word line activation signal WLOFFB through a gate. The first PMOS transistor P21 may transmit the high voltage VPP to the second node C_N1 according to the word line activation signal WLOFFB of a logic low level. The first NMOS transistor N21 may be coupled between the second node C_N1 and a ground voltage (VSS) node, and receive the first address information BAX_M0 through a gate. The first NMOS transistor N21 may enable the first main word line driver 242_0 by grounding the second node C_N1 according to the first address information BAX_M0. The second PMOS transistor P22 may be coupled between the high voltage (VPP) node and the second node C_N1, and receive a voltage at a third node C_N2 through a gate. The second PMOS transistor P22 may transmit the high voltage VPP to the second node C_N1 according to the voltage at the third node C_N2.

The third PMOS transistor P23 and the second NMOS transistor N22 may constitute a first inverter INV1. The first inverter INV1 may invert a voltage at the second node C_N1 and transmit the inverted voltage to the third node C_N2. The fourth PMOS transistor P24 and the third NMOS transistor N23 may constitute a second inverter INV2. The second inverter INV2 may invert the voltage at the third node C_N2 according to a voltage level at the first node VPPC_N (that is, a voltage level of the operating voltage VPPC0) and transmit the inverted voltage to a fourth node C_N3. The main driving signal MWLB<0> may be output from the fourth node C_N3.

With the above configuration, one of the main word line drivers 242_0 to 242_255 may be selected according to the first address information BAX_M #. When the word line activation signal WLOFFB of a logic high level is input, the selected main word line driver may drive the second node C_N1 as a ground voltage VSS, and accordingly, may output the main driving signal MWLB<0> as a ground voltage (VSS) level. On the other hand, when the word line activation signal WLOFFB of a logic low level is input, the selected main word line driver may drive the second node C_N1 as a high voltage VPP, and accordingly, may output the main driving signal MWLB<0> as an operating voltage (VPP0) level.

FIGS. 7A and 7B are detailed circuit diagrams illustrating the sub-word line driving circuit 246 of FIG. 4.

The sub-word line driving circuit 246 may include first to 2048-th sub-word line drivers (SWD) 246_0 to 246_2047.

The first to 2048-th sub-word line drivers 246_0 to 246_2047 may drive the first to 2048-th sub-word lines WL0 to WL2047 according to the main driving signal MWLB<0:255> and the first and second sub-driving signals FX<0:7> and FXB<0:7>.

As shown in Table 1 below, the first to 2048-th sub-word line drivers 246_0 to 246_2047 may control an activation and deactivation of the first to 2048-th sub-word lines WL0 to WL2047 in a combination of 256*8 using the 256-bit main driving signal MWLB<0:255>, the 8-bit first sub-driving signal FX<0:7> and the second sub-driving signal FXB<0:7>.

TABLE 1

| | | |
|---|---|---|
| WL0 | MWLB<0> | FX<0>, FXB<0> |
| WL1 | MWLB<0> | FX<1>, FXB<1> |
| WL2 | MWLB<0> | FX<2>, FXB<2> |
| WL3 | MWLB<0> | FX<3>, FXB<3> |
| WL4 | MWLB<0> | FX<4>, FXB<4> |
| WL5 | MWLB<0> | FX<5>, FXB<5> |
| WL6 | MWLB<0> | FX<6>, FXB<6> |
| WL7 | MWLB<0> | FX<7>, FXB<7> |
| WL8 | MWLB<1> | FX<0>, FXB<0> |
| WL9 | MWLB<1> | FX<1>, FXB<1> |
| WL10 | MWLB<1> | FX<2>, FXB<2> |
| WL11 | MWLB<1> | FX<3>, FXB<3> |
| WL12 | MWLB<1> | FX<4>, FXB<4> |
| WL13 | MWLB<1> | FX<5>, FXB<5> |
| WL14 | MWLB<1> | FX<6>, FXB<6> |
| WL15 | MWLB<1> | FX<7>, FXB<7> |
| WL16 | MWLB<2> | FX<0>, FXB<0> |
| WL17 | MWLB<2> | FX<1>, FXB<1> |
| . . . | . . . | . . . |
| WL510 | MWLB<63> | FX<6>, FXB<6> |
| WL511 | MWLB<63> | FX<7>, FXB<7> |

Referring to Table 1, the activation and deactivation of the fourth word line WL3 may be controlled based on the main driving signal MWLB<0>, the first sub-driving signal FX<3>, and the second sub-driving signal FXB<3>, and the activation and deactivation of the 18-th word line WL17 may be controlled based on the main driving signal MWLB<2>, the first sub-driving signal FX<1>, and the second sub-driving signal FXB<1>. The number of word lines described in the above embodiment and the number of bits of driving signals are only one example, and the embodiments are not limited thereto, and various word lines may be driven depending on a combination of bits of driving signals.

Since the first to 2048-th sub-word line drivers 246_0 to 246_2047 have substantially the same configuration, the first sub-word line driver 246_0 will be described as an example. Referring to FIG. 7B, the first sub-word line driver 246_0 may include a first PMOS transistor P31 and first and second NMOS transistors N31 and N32.

The first PMOS transistor P31 may have a source receiving the first sub-driving signal FX<0>, a gate receiving the main driving signal MWLB<0>, and a drain coupled to the first sub-word line WL0. The first PMOS transistor P31 may receive a high voltage VPP as a substrate voltage. Accordingly, when the main driving signal MWLB<0> is input to a logic low level, the first PMOS transistor P31 may drive the first sub-word line WL0 to a high voltage (VPP) level according to the first sub-driving signal FX<0>. The first NMOS transistor N31 may be coupled between a low voltage (VBBW) node and the first sub-word line WL0, and receive the main driving signal MWLB<0> as a gate. The first NMOS transistor N31 may drive the first sub-word line WL0 to a low voltage (VBBW) level in response to the main driving signal MWLB<0> of a logic high level. The second NMOS transistor N32 may be coupled between the first sub-word line WL0 and the low voltage (VBBW) node, and receive the second sub-driving signal FXB<0> through a gate. The second NMOS transistor N32 may drive the first sub-word line WL0 to the low voltage (VBBW) level in response to the second sub-driving signal FXB<0> of a logic high level.

Hereinafter, a soft landing operation of the memory device 100 according to an embodiment of the present disclosure will be described with reference to FIGS. 2 to 8.

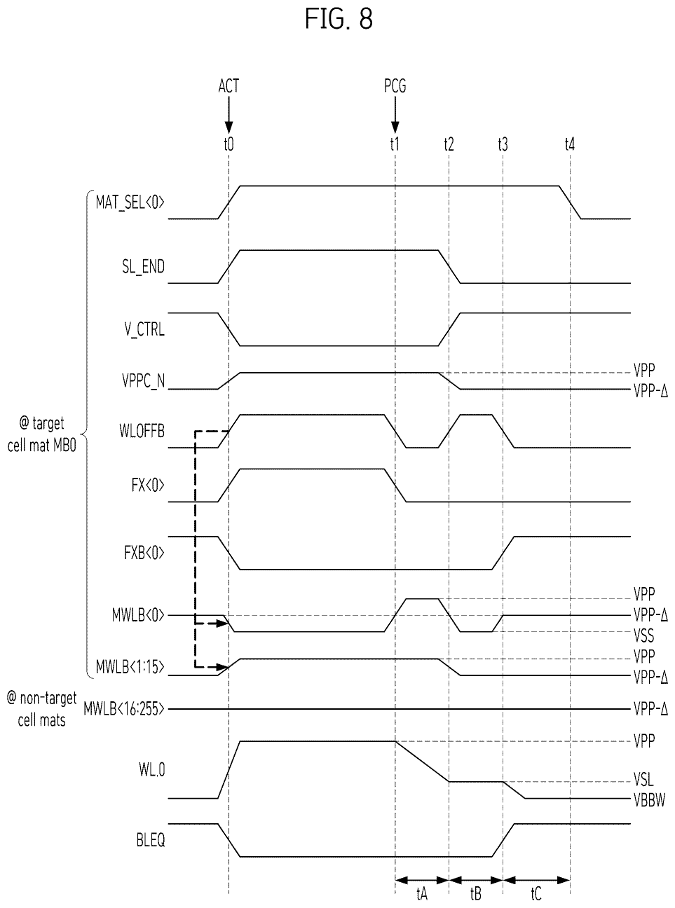

FIG. 8 is a waveform diagram for describing an operation of the memory device 100 according to an embodiment of the present disclosure.

Referring to FIG. 8, before a time point to, since all bits of the mat selection signal MAT_SEL<0:15> have a logic low level, the voltage supply circuit 230 may provide a second supply voltage VPP-Δ to all of the cell mats MB0 to MB15 as the operating voltages VPP0 to VPPC1. When a word line activation signal WLOFFB is deactivated to a logic low level, all of the main word line drivers 242_0 to 242_255 may output the main driving signals MWLB<0:255> to a second supply voltage (VPP-Δ) level.

At a point in time to, an active command ACT is input. The row decoder 210 may decode a row address RADD input together with the active command ACT to generate the mat selection signal MAT_SEL<0:15> for selecting one cell mat among the plurality of cell mats. Furthermore, the row decoder 210 may decode the row address RADD to generate the first address information BAX_M # for specifying one of the plurality of main word lines and the second address information BAX_S # for specifying one of eight sub-word lines allocated to one main word line. Hereinafter, it is illustrated that the first cell mat MB0 is selected and the first sub-word line WL0 constituting the first main word line allocated to the first cell mat MB0 is selected.

The control signal generation circuit 220 may generate the landing control signal SL_END to a logic high level and the word line activation signal WLOFFB to a logic high level, according to the active command ACT. Accordingly, only the voltage control signal V_CTRL corresponding to the selected first cell mat MB0 is activated to a logic low level, and the voltage supply circuit 230 provides the first supply voltage VPP to the selected first cell mat MB0 as the operating voltage VPPC0, while the second supply voltage VPP-Δ may be supplied to the remaining unselected cell mats MB1 to MB15 as the operating voltage VPPC1 to VPPC15.

The first main word line driver 242_0 may output the main driving signal MWLB<0> to a ground voltage (VSS) level according to the word line activation signal WLOFFB of the logic high level. The first sub-word line driver 246_0 may drive the first sub-word line WL0 to a high voltage (VPP) level according to the first sub-driving signal FX<0> of the logic high level. On the other hand, in the case of the second to 16-th main word line drivers 242_1 to 242_15 disposed in the first cell mat MB0, since the first NMOS transistor N21 which is a bias transistor is turned off, the second node C_N1 is floated and the third node C_N2 maintains the previous state, so that the main driving signal MWLB<1:15> may be output to a first supply voltage (VPP) level. In addition, the main driving signal MWLB<16:255> disposed in the unselected cell mats may maintain the second supply voltage (VPP-Δ) level. Here, a precharge signal BLEQ provided to the bit line sense amplifiers BLSA is deactivated to a logic low level according to the active command ACT, and accordingly, the bit line sense amplifiers BLSA may be activated to perform a sense amplification operation.

At a time point t1, a precharge command PCG is input. The control signal generation circuit 220 may deactivate the word line activation signal WLOFFB to a logic low level according to the precharge command PCG. In this case, the sub-word line control circuit 244 may transition the first sub-driving signal FX<0> to a logic low level. The first main word line driver 242_0 may output the main driving signal MWLB<0> to a first supply voltage (VPP) level, and the first sub-word line driver 246_0 may discharge the first sub-word line WL0 from a high voltage (VPP) level.

After that, at a time t2, the control signal generation circuit 220 may transition the landing control signal SL_END to a logic low level and activate the word line activation signal WLOFFB to a logic high level. The voltage control signal V_CTRL is deactivated to a logic high level according to the landing control signal SL_END of the logic low level. The voltage supply circuit 230 may supply the second supply voltage VPP-Δ to the selected first cell mat MB0 as the operating voltage VPP0. The first main word line driver 242_0 may output the main driving signal MWLB<0> to a ground voltage (VSS) level, and the first sub-word line driver 246_0 may maintain the first sub-word line WL0 at an intermediate voltage (VSL) level according to the first sub-driving signal FX<0> of the logic low level. Accordingly, a first section tA in which the first sub-word line WL0 decreases from the high voltage (VPP) level to the intermediate voltage (VSL) level may be defined between the time point t1 and the time point t2, and a second section tB in which the first sub-word line WL0 maintains the intermediate voltage (VSL) level may be defined between the time point t2 and the time point t3.

At a time point t3, the control signal generation circuit 220 may deactivate the word line activation signal WLOFFB to a logic low level, and the sub-word line control circuit 244 may transition the second sub-driving signal FXB<0> to a logic high level. The first main word line driver 242_0 may output the main driving signal MWLB<0> to a second supply voltage (VPP-Δ) level, and the first sub-word line driver 246_0 may discharge the first sub-word line WL0 to a low voltage (VBBW) level according to the second sub-driving signal FXB<0> of the logic high level. Accordingly, a third section tC in which the first sub-word line WL0 decreases from the intermediate voltage (VSL) level to the low voltage (VBBW) level may be defined between the time point t3 and the time point t4. In this case, the precharge signal BLEQ provided to the bit line sense amplifiers BLSA may be activated to a logic high level according to the precharge command PCG, and accordingly, the bit line sense amplifiers BLSA may precharge bit lines.

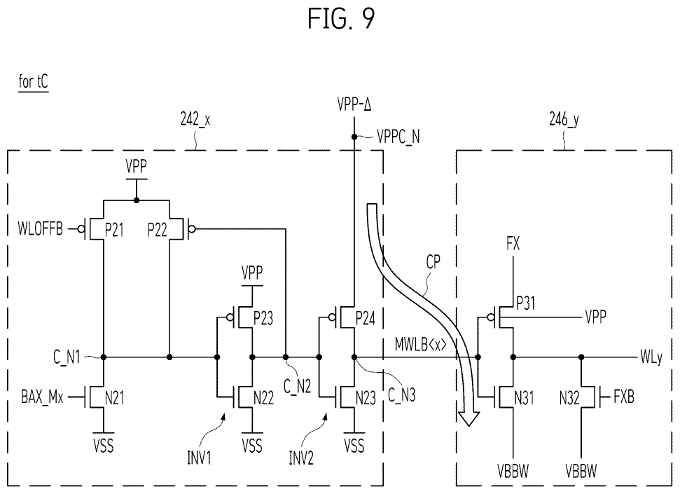

Here, as illustrated in FIG. 9, the main word line driver 242_x, where x is an integer between 0 and 255, may be supplied with the second supply voltage VPP-Δ through the first node VPPC_N during the third section tC to drive the main driving signal MWLB<x>. Accordingly, a magnitude of a stress applied to the PMOS transistor P31 included in the sub-word line driver 246_y, where y is an integer between 0 and 2047, may be reduced. Furthermore, a current path CP is formed between the first node VPPC_N of the main word line driver 242_x and the low voltage (VBBW) node of the sub-word line driver 246_y during the third section tC. Accordingly, a switching time from the first supply voltage (VPP) level to the second supply voltage (VPP-Δ) level may be reduced without arranging a separate leaker circuit, and thus a stabilizing speed of the voltage applied to the sub-word line driver 246_y may be increased. As described above, the memory device according to an embodiment of the present disclosure may prevent deterioration of discharge characteristics of selected sub-word lines and reduce leakage current of unselected sub-word line drivers by supplying the operating voltage of the main word line driver to a voltage less than the high voltage by a certain level after the second section tB of the soft landing operation. Accordingly, it is possible to mitigate the row hammer during the precharge operation and prevent a tRP logic failure.

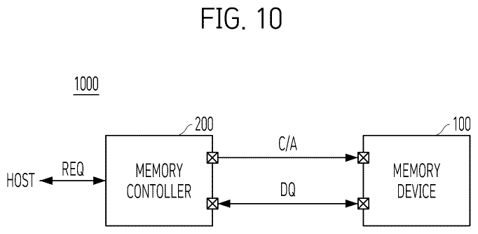

FIG. 10 is a block diagram illustrating a memory system 1000 according to an embodiment of the present disclosure.

Referring to FIG. 10, the memory system 1000 may include the memory device 100 and a memory controller 200.

The memory controller 200 may control the overall operation of the memory system 1000 and control overall data exchange between a host and the memory device 100. The memory controller 200 may generate a command/address signal C/A in response to a request REQ from the host and provide the command/address signal C/A to the memory device 100. According to an embodiment, the memory controller 200 may provide to the memory device 100 a clock together with the command/address signal C/A. The memory controller 200 may provide to the memory device 100 data DQ corresponding to the request REQ provided from the host. The memory controller 200 may provide to the host the data DQ read from the memory device 100. The command/address signal C/A provided by the memory controller 200 to the memory device 100 may include an active command ACT, a precharge command PCG, a read command RD, and a write command WT.

The memory device 100 may have substantially the same configuration as the memory device 100 of FIG. 1. The memory device 100 may perform a soft landing operation for driving a word line WL by dividing into a first section tA in which a voltage level of the word line WL decreases from a high voltage (VPP) level to an intermediate voltage (VSL) level, a second section tB in which the intermediate voltage (VSL) level is maintained, and a third section tC in which the voltage level of the word line WL decreases from the intermediate voltage (VSL) level to a low voltage (VBBW) level. In particular, according to an embodiment of the present disclosure, the memory device 100 may supply an operating voltage of a main word line driver to a voltage less than a high voltage by a certain level during the second section tB and third section tC of the soft landing operation, thereby reducing leakage current of unselected sub-word line drivers and preventing deterioration of discharge characteristics of a selected sub-word line. Further, the memory device 100 may drive a main driving signal (or main word line) to a voltage less than a high voltage by a certain level during the third section tC, thereby further alleviating a slope of the selected sub-word line and mitigating the row hammer.

Various embodiments of the present disclosure have been described in the drawings and specification. Although specific terminologies are used here, the terminologies are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein. The embodiments may be combined to form additional embodiments.

It should be noted that although the technical spirit of the disclosure has been described in connection with embodiments thereof, this is merely for description purposes and should not be interpreted as limiting. It should be appreciated by one of ordinary skill in the art that various changes may be made thereto without departing from the technical spirit of the disclosure and the following claims.

For example, for the logic gates and transistors provided as examples in the above-described embodiments, different positions and types may be implemented depending on the polarity of the input signal.

What is claimed is:

1. A memory device comprising:
cell mats in which a plurality of sub-word lines are arranged;
a control signal generation circuit configured to generate a landing control signal to perform a soft landing operation on the plurality of sub-word lines according to a precharge command;
a voltage supply circuit configured to provide a first supply voltage or a second supply voltage as an operating voltage according to a mat selection signal for selecting one of the cell mats and the landing control signal, the second supply voltage being less than the first supply voltage; and
a word line driving circuit configured to drive a sub-word line selected by a row address, among the plurality of sub-word lines, based on the operating voltage.

2. The memory device of claim 1, wherein the control signal generation circuit is configured to:
generate the landing control signal by dividing the soft landing operation into a first section, a second section, and a third section,
in the first section, a voltage level of the selected sub-word line decreases from a first voltage level to a second voltage level,
in the second section, the second voltage level is maintained, and
in the third section, the voltage level of the selected sub-word line decreases from the second voltage level to a third voltage level.

3. The memory device of claim 2, wherein the landing control signal distinguishes the second section and/or the third section, from the first section.

4. The memory device of claim 2,
wherein the plurality of sub-word lines are grouped to form main word lines.

5. The memory device of claim 4,
wherein the voltage supply circuit is configured to:
provide, during the first section, the first supply voltage to main word lines allocated to a cell mat including the selected sub-word line, and the second supply voltage to main word lines allocated to the remaining cell mats, and
provide, during the second section and the third section, the second supply voltage to the main word lines allocated to all cell mats.

6. The memory device of claim 1,
wherein the voltage supply circuit includes cell mat voltage supply circuits respectively corresponding to the cell mats, and
wherein each of the cell mat voltage supply circuits includes:
a control part configured to generate a voltage control signal according to the landing control signal and the mat selection signal; and
a supply part configured to provide the first supply voltage or the second supply voltage as the operating voltage according to the voltage control signal.

7. The memory device of claim 6, wherein the supply part includes:
a first transistor coupled between a high voltage node and a first node to receive the voltage control signal; and
one or more transistors diode-connected in series between the high voltage node and the first node, wherein the operating voltage is output from the first node.

8. The memory device of claim 1, wherein the word line driving circuit includes:
a main word line driving circuit configured to receive the operating voltage and generate a main driving signal in response to first address information, which is included in the row address, and a word line activation signal;
a sub-word line control circuit configured to generate a sub-driving signal in response to second address information, which is included in the row address, and the word line activation signal; and
a sub-word line driving circuit configured to drive the selected sub-word line according to the main driving signal and the sub-driving signal.

9. The memory device of claim 8,
wherein the plurality of sub-word lines are grouped to form main word lines.

10. The memory device of claim 9,
wherein the first address information includes information for selecting one of the main word lines, and the second address information includes information for selecting one of the sub-word lines allocated to the selected main word line.

11. A memory device comprising:
cell mats in which a plurality of main word lines are allocated;
a plurality of main word line drivers configured to drive the plurality of main word lines based on an operating voltage; and
a voltage supply circuit configured to selectively provide a first supply voltage or a second supply voltage, as the operating voltage, to main word line drivers driving main word lines allocated to a cell mat selected by a mat selection signal, according to a landing control signal for performing a soft landing operation for a precharge operation on the plurality of main word lines, the second supply voltage being less than the first supply voltage.

12. The memory device of claim 11, further comprising:
a control signal generation circuit configured to generate the landing control signal by dividing the soft landing operation into a first section, a second section, and a third section,
the first section corresponds to discharging from a high voltage level to an intermediate voltage level,
the second section corresponds to maintaining the intermediate voltage level, and
the third section corresponds to discharging from the intermediate voltage level to a low voltage level, during the precharge operation.

13. The memory device of claim 12,
wherein the landing control signal distinguishes the second section and/or the third section, from the first section.

14. The memory device of claim 12, wherein the voltage supply circuit is configured to:
provide, during the first section, the first supply voltage to the main word lines allocated to the selected cell mat, and the second supply voltage to the main word lines allocated to the remaining cell mats, and
provide, during the second section and the third section, the second supply voltage to the main word lines allocated to all cell mats.

15. The memory device of claim 12, further comprising:
a plurality of sub-word line drivers configured to drive sub-word lines grouped to form one main word line of the plurality of main word lines.

16. The memory device of claim 15,
wherein each of the plurality of main word line drivers includes a first type of transistor that receives the operating voltage through a first node and drives a corresponding main word line,
wherein each of the sub-word line drivers includes a second type of transistor that is coupled between a corresponding sub-word line and a ground node, and has a gate coupled to the corresponding main word line,
wherein, during the third section, a current path is formed between the first node, the first type of transistor, the second type of transistor, and the ground node.

17. An operating method of a memory device including cell mats in which a plurality of main word lines are allocated, wherein a plurality of sub-word lines are grouped to form one main word line of the plurality of main word lines, the operating method comprising:
receiving a precharge command;
providing a first supply voltage to main word lines allocated to a cell mat including a sub-word line selected from the plurality of sub-word lines while first discharging the selected sub-word line from a first voltage level to a second voltage level; and
providing a second supply voltage to main word lines allocated to all cell mats while second discharging the selected sub-word line from the second voltage level to a third voltage level, the second supply voltage being less than the first supply voltage.

18. The operating method of claim 17, further comprising:
maintaining the second voltage level of the selected sub-word line between the first discharging and the second discharging.

19. The operating method of claim 17, further comprising:
providing the second supply voltage to main word lines allocated to the remaining cell mats during the first discharging.
